(19) United States
(12) Patent Application Publication
(10) Pub. No.: US 2022/0109094 A1
(43) Pub. Date: Apr. 7, 2022

(54) THERMOELECTRIC SYSTEMS AND METHODS OF APPLYING THE SAME

(71) Applicant: Matrix Industries, Inc., Menlo Park, CA (US)

(72) Inventors: Haifan LIANG, Menlo Park, CA (US); Arjun MENDIRATTA, Menlo Park, CA (US); Tristan DAY, Menlo Park, CA (US); Douglas W. THAM, Menlo Park, CA (US); Akram I. BOUKAI, Menlo Park, CA (US)

(21) Appl. No.: 17/308,289

(22) Filed: May 5, 2021

Related U.S. Application Data
(63) Continuation of application No. PCT/US2019/060152, filed on Nov. 6, 2019.
(60) Provisional application No. 62/756,691, filed on Nov. 7, 2018.

(51) Int. Cl. H01L 35/32; F24S 60/00

(52) U.S. Cl. CPC H01L 35/32; F28F 2275/025; F24S 60/00

(57) ABSTRACT

Provided herein is a thermoelectric system for generating electricity using ambient temperature oscillations (e.g., between day and night time). The thermoelectric system may comprise a first heat exchanger, a thermoelectric generator, one or more heat conducting units, a second heat exchanger, and a container configured to (i) contain the second heat exchanger and a thermal storage material and (ii) insulate the thermal storage material from an external to the container.

### CROSS-REFERENCE

This is a continuation of International Application No. PCT/US2019/060152, filed on Nov. 6, 2019, which claims the benefit of U.S. Provisional Patent Application No. 62/756,691, filed on Nov. 7, 2018, each of which are hereby incorporated by reference in their entireties.

### BACKGROUND

Over 15 Terawatts of heat may be lost to the environment annually around the world by heat engines that require petroleum as their primary fuel source. This is because these engines may only convert about 30% to 40% of petroleum's chemical energy into useful work. Waste heat generation may be an unavoidable consequence of the second law of thermodynamics.

The term “thermoelectric effect” encompasses the Seebeck effect, Peltier effect and Thomson effect. Solid-state cooling and power generation based on thermoelectric effects may typically employ the Seebeck effect or Peltier effect for power generation and heat pumping. The utility of such conventional thermoelectric devices may, however, be limited by their low coefficient-of-performance (COP) (for refrigeration applications) or low efficiency (for power generation applications).

Thermoelectric device performance may be captured by a so-called thermoelectric figure-of-merit, Z=S²σ/k, where ‘S’ is the Seebeck coefficient, ‘σ’ is the electrical conductivity, and ‘k’ is thermal conductivity. Z may typically be employed as the indicator of the COP and the efficiency of thermoelectric devices—that is, COP scales with Z. A dimensionless figure-of-merit, ZT, may be employed to quantify thermoelectric device performance, where ‘T’ can be an average temperature of the hot and the cold sides of the device.

Applications of conventional semiconductor thermoelectric coolers may be rather limited, as a result of a low figure-of-merit, despite many advantages that they provide over other refrigeration technologies. In cooling, low efficiency of thermoelectric devices made from conventional thermoelectric materials with small figure-of-merit limits their applications in providing efficient thermoelectric cooling.

### SUMMARY

Provided herein is a thermoelectric system for generating electric energy through temperature difference between a thermal storage material inside the thermoelectric system and an ambient environment. The thermoelectric system may generate electricity using ambient temperature oscillations (e.g., between day and night time) for indoors and outdoors. A container may be used to hold the thermal storage material. The container may be formed of thermally insulating material. The thermal storage material may comprise water or polyethylene glycol, for example. The thermoelectric system may be configured to control the flow of heat between the thermal storage material and the ambient environment. The thermoelectric system may comprise heat sinks, heat pipes and thermoelectric generators. The difference in temperature between the ambient environment and insulated thermal storage material may allow temperature difference across the thermoelectric generator, which may generate electricity due to the Seebeck effect.

In an aspect, a thermoelectric system comprises a first heat exchanger configured to collect thermal energy from or dissipate the thermal energy to an ambient environment; a thermoelectric generator comprising a plurality of thermoelectric elements, wherein the thermoelectric generator is coupled to and in thermal communication with the first heat exchanger; one or more heat conducting units coupled to the thermoelectric generator; a second heat exchanger coupled to and in thermal communication with the one or more heat conducting units; and a container configured to (i) contain the second heat exchanger and a thermal storage material, and (ii) insulate the thermal storage material from an external to the container such that a rate of heat exchange between the thermal storage material and the ambient environment through the container is at most about 10 W, wherein when the second heat exchanger is in the container, the second heat exchanger collects the thermal energy from or dissipates the thermal energy to the thermal storage material.

In some embodiments, the first heat exchanger is a heat sink. In some embodiments, the heat sink has a surface area between 400 millimeters squared (mm²) and 100000 mm². In some embodiments, the system further comprises a thermally conductive adhesive disposed between the thermoelectric generator and the first heat exchanger, wherein the thermally conductive adhesive has a thermal conductivity of at least 0.5 Watts/meter-Kelvin (W/m-K) at a temperature of 25° C. In some embodiments, the system further comprises an additional thermally conductive adhesive disposed between the thermoelectric generator and the one or more heat conducting units, wherein the additional thermally conductive adhesive has a thermal conductivity of at least 0.5 W/m-K at a temperature of 25° C.

In some embodiments, the one or more heat conducting units comprise a thermally conductive material. In some embodiments, the thermally conductivity material has a thermal conductivity of at least 1 W/m-K at a temperature of 25° C. In some embodiments, the container comprises a first insulation component and a second insulation component, wherein the first insulation component seals the second insulation component. In some embodiments, the first insulation component is a cover and the second insulation component is a tank. In some embodiments, the thermoelectric generator generates power upon flow of the thermal energy (i) from the first heat exchanger to the thermoelectric generator, or (ii) from the second heat exchanger to the thermoelectric generator.

In another aspect, a method for generating power comprises: providing a thermoelectric system comprising (i) a first heat exchanger configured to collect thermal energy from or dissipate the thermal energy to an ambient environment; (ii) a thermoelectric generator comprising a plurality of thermoelectric elements, wherein the thermoelectric generator is coupled to and in thermal communication with the first heat exchanger; (iii) one or more heat conducting units coupled to the thermoelectric generator; (iv) a second heat exchanger coupled to and in thermal communication with the one or more heat conducting units; and (v) a container configured to (i) contain the second heat exchanger and a thermal storage material and (ii) insulate the thermal storage material from an external to the container such that a rate of heat exchange between the thermal storage material and the ambient environment through the container is at most about 10 Watts (W), wherein when the second heat exchanger is in the container, the second heat exchanger collects the thermal energy from or dissipates the thermal energy to the thermal storage material; using the thermoelectric generator to generate power upon flow of the thermal energy (i) from the first heat exchanger to the thermoelectric generator, or (ii) from the second heat exchanger to the thermoelectric generator; and directing the power to an energy storage system or an electrical load.

In some embodiments, the first heat exchanger is a heat sink. In some embodiments, the heat sink has a surface area between 400 mm² and 100000 mm². In some embodiments, the thermoelectric system further comprises a thermally conductive adhesive disposed between the thermoelectric generator and the first heat exchanger, wherein the thermally conductive adhesive has a thermal conductivity of at least 0.5 W/m-K at a temperature of 25° C. In some embodiments, the thermoelectric system further comprises an additional thermally conductive adhesive disposed between the thermoelectric generator and the one or more heat conducting units, wherein the additional thermally conductive adhesive has a thermal conductivity of at least 0.5 W/m-K at a temperature of 25° C.

In some embodiments, the one or more heat conducting units comprise a thermally conductive material. In some embodiments, the thermally conductive material has a thermal conductivity of at least 1 W/m-K at a temperature of 25° C. In some embodiments, the container comprises a first insulation component and a second insulation component, wherein the first insulation component seals the second insulation component. In some embodiments, the first insulation component is a cover and the second insulation component is a tank. In some embodiments, at least a portion of the power is stored in the energy storage system or used in the electrical load.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “figure” and “FIG.” herein), of which:

FIG. 1 shows an example of a thermoelectric system described herein; and

FIG. 2 shows a computer system that is programmed or otherwise configured to implement methods provided herein.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “nanostructure,” as used herein, generally refers to structures having a first dimension (e.g., width) along a first axis that is less than about 1 micrometer (“micron”) in size. Along a second axis orthogonal to the first axis, such nanostructures can have a second dimension from nanometers or smaller to microns, millimeters or larger. The dimension (e.g., width) may be less than about 1000 nanometers (“nm”), or 500 nm, or 100 nm, or 50 nm, or smaller. Nanostructures can include holes formed in a substrate material. The holes can form a mesh having an array of holes. In other cases, nanostructure can include rod-like structures, such as wires, cylinders or box-like structure. The rod-like structures can have circular, elliptical, triangular, square, rectangular, pentagonal, hexagonal, heptagonal, octagonal or nonagonal, or other cross-sections.

The term “nanowire,” as used herein, generally refers to a wire or other elongate structure having a width or diameter that is less than or equal to about 1000 nm, or 500 nm, or 100 nm, or 50 nm, or smaller.

The term “n-type,” as used herein, generally refers to a material that is chemically doped (“doped”) with an n-type dopant. For instance, silicon can be doped n-type using phosphorous or arsenic.

The term “p-type,” as used herein, generally refers to a material that is doped with a p-type dopant. For instance, silicon can be doped p-type using boron or aluminum.

The term “metallic,” as used herein, generally refers to a substance exhibiting metallic properties. A metallic material can include one or more elemental metals.

The term “adjacent” or “adjacent to,” as used herein, includes “next to,” “adjoining,” “in contact with,” and “in proximity to.” In an example, a first unit adjacent to a second unit is directly in contact with the second unit. As another example, the first unit is adjacent to the second unit with one or more intervening units between the first unit and the second unit.

The word “coupled,” as used herein, generally refers to at least one unit being directly or indirectly attached to at least another unit. In some examples, a thermoelectric generator coupled to a heat exchanger may be directly attached to the heat exchanger or indirectly attached to the heat exchanger. For example, the thermoelectric generator is directly attached to the heat exchanger using a thermally conductive material (e.g., a thermally conductive adhesive). As another, the thermoelectric generator is indirectly attached to the heat exchanger through another unit, such as a heat conducting pipe.

### Thermoelectric Systems

In an aspect, the present disclosure provides thermoelectric systems for generating power or providing heating and/or cooling. A thermoelectric system may comprise a first heat exchanger configured to collect thermal energy from or dissipate the thermal energy to an ambient environment, and a thermoelectric generator comprising a plurality of thermoelectric elements. The thermoelectric generator may be coupled to and in thermal communication with the first heat exchanger. The thermoelectric system may further comprise one or more heat conducting units coupled to the thermoelectric generator, a second heat exchanger coupled to and in thermal communication with the one or more heat conducting units, and a container configured to (i) contain the second heat exchanger and a thermal storage material and (ii) insulate the thermal storage material from an external to the container such that a rate of heat exchange between the thermal storage material and the ambient environment through the container is at most about 10 watts (W). When the second heat exchanger is in the container, the second heat exchanger may collect the thermal energy from or dissipates the thermal energy to the thermal storage material.

The ambient environment may be an environment open to the atmosphere. For example, at sea level, a pressure of the ambient environment may be 1 atmosphere. The ambient environment may be at a temperature that is governed by one or more environmental factors (e.g., cloud coverage, humidity, orientation of the Earth with respect to the sun, etc.).

The first heat exchanger may be configured for placement in an ambient environment. The ambient environment may be above or below a surface. The surface may be a ground surface or a water surface. The first heat exchanger may be configured to collect thermal energy from or dissipate thermal energy to a location in the ambient environment. For example, depending on the time of a day, a location in the ambient environment may be cooler than a thermal storage material inside the thermoelectric system, in which case the first heat exchanger may dissipate thermal energy to the ambient environment. As another example, the location in the ambient environment may be warmer than the thermal storage material inside the thermoelectric system, in which case the first heat exchanger may collect thermal energy from the ambient environment.

If the first heat exchanger collects thermal energy, the first heat exchanger may provide the heat to adjacent components (e.g., a thermoelectric generator). If the first heat exchanger dissipates thermal energy, the first heat exchanger may expel the thermal energy from adjacent components (e.g., a thermoelectric generator). The first heat exchanger can be sufficiently thermally conductive to remove heat from the adjacent components and expel it to the environment.

The first heat exchanger may comprise one or more heat sinks. The heat sink can aid in collecting or dissipating heat. A heat sink can include one or more heat fins which can be sized and arranged to provide increased heat transfer area. A heat sink may be any flexible material, which can be sufficiently thermally conductive to provide a low thermal resistance (e.g., thermal resistance of at most about 1 Kelvin/Watt) and sufficiently thin (e.g., thickness from about 0.01 millimeter to 1 millimeter) to bend in a flexible manner. The heat sink may be any design, shape, and/or size. The heat sink can be within or in contact with a matrix. The matrix can be a polymer foil, elastomeric polymer, ceramic foil, semiconductor foil, insulator foil, insulated metal foil or combinations thereof. To increase the surface area presented to the ambient environment for effective thermal transfer, the matrix may be patterned with dimples, corrugations, pins, fins or ribs.

The heat sink may be formed of electrically insulating material, which can be sufficiently thin (e.g., thickness from about 0.01 millimeter to 1 millimeter) to present a low thermal resistance (e.g., thermal resistance of at most 1 Kelvin/Watt (K/W)). Examples of the insulating material include polymer foil (e.g., polyethylene, polypropylene, polyester, polystyrene, polyimide, etc.); elastomeric polymer foil (e.g., polydimethylsilazane, polyisoprene, natural rubber, etc.); fabric (e.g., conventional cloths, fiberglass mat, etc.); ceramic, semiconductor, or insulator foil (e.g., glass, silicon, silicon carbide, silicon nitride, aluminum oxide, aluminum nitride, boron nitride, etc.); insulated metal foil (e.g., anodized aluminum or titanium, coated copper or steel, etc.); or combinations thereof. The electrically insulating material can be both flexible and stretchable when an elastomeric material is used.

The heat sink may have a surface area between about 400 millimeter² (mm²) and 100000 mm², 300 mm² and 110000 mm², 200 mm² and 120000 mm², 100 mm² and 130000 mm², 50 mm² and 140000 mm², or 10 mm² and 150000 mm². The heat sink may have a surface area of at least 100 mm², 200 mm², 300 mm², 400 mm², 500 mm², 1000 mm², 2000 mm², 3000 mm², 4000 mm², 5000 mm², 10000 mm² or greater. In some cases, the heat sink may have a surface area of at most 150000 mm², 100000 mm², 50000 mm², 40000 mm², 30000 mm², 10000 mm², 5000 mm², 3000 mm², 1000 mm², 500 mm², 100 mm² or less.

The heat sink may have a height between about 5 millimeter (mm) and 500 mm, 4 mm and 600 mm, 3 mm and 700 mm, 2 mm and 800 mm, or 1 mm and 900 mm. The heat sink may have a height of at least 5 mm, 10 mm, 50 mm, 100 mm, 200 mm, 300 mm, 400 mm, 500 mm, or greater. In some cases, the heat sink may have a height of at most 500 mm, 400 mm, 300 mm, 200 mm, 100 mm, 10 mm, 5 mm, or less. The heat sink may have a thermal resistance between about 1 Kelvin/Watt (K/W) and 100 K/W, 5 K/W and 90 K/W, 10 K/W and 85 K/W, 15 K/W and 80 K/W, 20 K/W and 75 K/W, or 25 K/W and 70 K/W. The heat sink may have a thermal resistance of at least 1 K/W, 10 K/W, 20 K/W, 30 K/W, 40 K/W, 50 K/W, 60 K/W, 70 K/W, 80 K/W, 90 K/W, 100 K/W, or greater. In some cases, heat sink may have a thermal resistance of at most 100 K/W, 90 K/W, 80 K/W, 70 K/W, 60 K/W, 50 K/W, 40 K/W, 30 K/W, 20 K/W, 10 K/W, or less. The heat sink may be of any design, shape, and/or size. In an example, a 40 mm×40 mm×25 mm aluminum heat sink with thermal resistance of 5 K/W is used.

The first heat exchanger may be of any design, shape, and/or size. The first heat exchanger may comprise one or more heat exchanger components. The heat exchanger components may be any design, shape, and/or size. Examples of possible shapes or designs include but are not limited to: mathematical shapes (e.g., circular, triangular, square, rectangular, pentagonal, or hexagonal), two-dimensional geometric shapes, multi-dimensional geometric shapes, curves, polygons, polyhedral, polytopes, minimal surfaces, ruled surfaces, non-orientable surfaces, quadrics, pseudospherical surfaces, algebraic surfaces, miscellaneous surfaces, riemann surfaces, box-drawing characters, cuisenaire rods, geometric shapes, shapes with metaphorical names, symbols, unicode geometric shapes, other geometric shapes, partial shapes or combination of shapes thereof. The number of heat exchanger components of the first heat exchanger may be at least 1, 2, 3, 4, 5, 6, 7, 8, 9, 10, or more.

The first heat exchanger may be formed of a metallic (or metal-containing) material. The metallic material may include one or more elemental metals (e.g., a pure metal or metal alloy). For example, the metallic material may include one or more of aluminum, titanium, iron, steel, copper, tin, tungsten, molybdenum, tantalum, cobalt, bismuth, cadmium, titanium, zirconium, antimony, manganese, beryllium, chromium, germanium, vanadium, gallium, hafnium, indium, niobium, rhenium, thallium, and their alloys. The first heat exchanger may be formed of a semiconductor-containing material, such as silicon or a silicide. The first heat exchanger may be formed of a polymeric material. The polymeric material may include one or more polymers. For example, the polymeric material may include one or more of polyvinyl chloride, polyvinylidene chloride, polyethylene, polyisobutene, and poly[ethylene-vinylacetate]copolymer. The first heat exchanger may be formed of a composite material. The composite material may include, for example, reinforced plastics, ceramic matrix composites, and metal matrix composites.

The thermoelectric system may comprise a thermoelectric generator. The thermoelectric generator may comprise a plurality of thermoelectric elements. The plurality of thermoelectric elements may be in thermal communication with the first heat exchanger. The plurality of thermoelectric elements may be in thermal communication with one or more heat conducting units. The plurality of thermoelectric elements may be in thermal communication with the second heat exchanger. The plurality of thermoelectric elements can be used to generate power upon the application of a temperature gradient across the plurality of thermoelectric elements. Such power can be used to provide electrical energy to various types of devices, such as consumer electronic devices. The plurality of thermoelectric elements may be n-type and p-type couples.

A given thermoelectric element of the plurality of thermoelectric elements can have various non-limiting advantages and benefits. The given thermoelectric element can have substantially high aspect ratios, uniformity of holes or wires, and figure-of-merit, ZT, which can be suitable for optimum thermoelectric performance. With respect to the figure-of-merit, Z can be an indicator of coefficient-of-performance (COP) and the efficiency of the given thermoelectric element, and T can be an average temperature of the hot and the cold sides of the given thermoelectric element. The figure-of-merit (ZT) of the given thermoelectric element may be at least about 0.01, 0.02, 0.03, 0.04, 0.05, 0.06, 0.07, 0.08, 0.09, 0.1, 0.15, 0.2, 0.25, 0.3, 0.35, 0.4, 0.45 0.5, 0.55, 0.6, 0.65, 0.7, 0.75, 0.8, 0.85, 0.9, 0.95, 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0 or greater at 25° C. The figure-of-merit may be from about 0.2 to 5, 0.01 to 3, 0.1 to 2.5, 0.5 to 2.0 or 0.5 to 1.5 at 25° C. The figure of merit (ZT) can be a function of temperature. The ZT may increase with temperature.

The plurality of thermoelectric elements may be disposed between electrodes. The plurality of thermoelectric elements may comprise an array of nanostructures (e.g., holes or wires). The array of nanostructures can include a plurality of holes or elongate structures, such as wires (e.g., nanowires). The holes or wires can be ordered and have uniform sizes and distributions. As an alternative, the holes or wires may not be ordered and may not have a uniform distribution. The holes or wires may intersect each other in random directions. A given thermoelectric element of the plurality of thermoelectric elements can be either p-type or n-type.

The plurality of thermoelectric elements may be flexible or substantially flexible. A flexible material can be a material that can be conformed to a shape, twisted, or bent without experiencing plastic deformation. This can enable the thermoelectric elements to be used in various settings, such as settings in which contact area with a heat source or heat sink may be important. The plurality of thermoelectric elements can include at least one semiconductor element which can be flexible. Individual semiconductor elements may be rigid but substantially thin (e.g., 500 nm to 1 mm or 1 micrometer to 0.5 mm) such that they provide a flexible thermoelectric element when disposed adjacent one another.

The thermoelectric generator may be coupled to the first heat exchanger. The thermoelectric generator may be in thermal communication with the first heat exchanger. The thermoelectric generator may comprise n-type and p-type couples. The number of the n-type and p-type couples may be between 10 and 1000, 50 and 900, 100 and 800, 200 and 700, 300 and 600, or 400 and 500. The number of n-type and p-type couples may be at least 10, 50, 100, 200, 300, 400, 500, 1000, or greater. In some cases, the number of n-type and p-type couples may be at most 1000, 500, 400, 300, 200, 100, 50, 10, or less.

The thermoelectric generator may have a thermal resistance between about 1 K/W and 1000 K/W, 5 K/W and 900 K/W, 10 K/W and 850 K/W, 15 K/W and 800 K/W, 20 K/W and 750 K/W, or 25 K/W and 700 K/W. The thermoelectric generator may have a thermal resistance of at least 1 K/W, 10 K/W, 20 K/W, 30 K/W, 40 K/W, 50 K/W, 100 K/W, 200 K/W, 500 K/W, 800 K/W, 1000 K/W, or greater. In some cases, the thermoelectric generator may have a thermal resistance of at most 1000 K/W, 800 K/W, 500 K/W, 300 K/W, 200 K/W, 50 K/W, 40 K/W, 30 K/W, 20 K/W, 10 K/W, or less. The figure-of-merit (ZT) of the thermoelectric generator may be at least about 0.01, 0.02, 0.03, 0.04, 0.05, 0.06, 0.07, 0.08, 0.09, 0.1, 0.15, 0.2, 0.25, 0.3, 0.35, 0.4, 0.45 0.5, 0.55, 0.6, 0.65, 0.7, 0.75, 0.8, 0.85, 0.9, 0.95, 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0 or greater at 25° C.

The thermoelectric generator may be formed of thermoelectric material. The thermoelectric material may be commercially available thermoelectric material. The thermoelectric material may comprise bismuth chalcogenides and their nanostructures, lead telluride, inorganic clathrates, magnesium group IV compounds, silicides, skutterudite thermoelectrics, oxide thermoelectrics, half heusler alloys, electrically conducting organic materials, silicon-germanium, sodium cobaltate, and amorphous materials. The bismuth chalcogenides and their nanostructures may comprise bismuth tellurium.

A current may be generated upon flow of at least the portion of thermal energy through the thermoelectric generator. The current can be a direct current (“DC”), alternating current (“AC”), or a combination of DC and AC. If the current is AC, a AC resistance may be at least 1 Ohm, 2 Ohms, 3 Ohms, 4 Ohms, 5 Ohms, 10 Ohms, 20 Ohms, 30 Ohms, 40 Ohms, 50 Ohms, 100 Ohms, 200 Ohms, 300 Ohms, 400 Ohms, 500 Ohms, 600 Ohms, 700 Ohms, 800 Ohms, 900 Ohms, 1000 Ohms, or greater. In some cases, the AC resistance may be at most 1000 Ohm, 500 Ohm, 400 Ohms, 300 Ohms, 200 Ohms, 100 Ohms, 50 Ohms, 40 Ohms, 30 Ohms, 20 Ohms, 10 Ohms, 5 Ohms, 4 Ohms, 3 Ohms, 2 Ohms, 1 Ohms, or less. The AC resistance may be between 1 Ohm and 1000 Ohms, 10 Ohms and 900 Ohms, 50 Ohms and 800 Ohms, 100 Ohms and 700 Ohms, 200 Ohms and 600 Ohms, or 300 Ohms and 500 Ohms. In one example, the thermoelectric generator comprises 127 n-type and p-type couples, has a ZT of 0.7, and has an AC resistance of 9 Ohms.

The thermoelectric system may comprise one or more heat conducting units. The one or more heat conducting units may comprise one or more conductive plates, or one or more heat pipes. A heat conducting unit of the one or more heat conducting units may be coupled to the thermoelectric generator. The heat conducting unit may be configured for placement adjacent to the thermoelectric generator. The heat conducting unit may be formed of a metallic (or metal-containing) material. The metallic material may include one or more elemental metals. For example, the metallic material may include one or more of aluminum, titanium, copper, iron, steel, tin, tungsten, molybdenum, tantalum, cobalt, bismuth, cadmium, titanium, zirconium, antimony, manganese, beryllium, chromium, germanium, vanadium, gallium, hafnium, indium, niobium, rhenium and thallium, and their alloys. The heat conducting unit may be formed of a semiconductor-containing material, such as silicon or a silicide. The heat conducting unit may be formed of a polymeric material. The polymeric material may include one or more polymers. For example, the polymeric material may include one or more of polyvinyl chloride, polyvinylidene chloride, polyethylene, polyisobutene, and poly[ethylene-vinylacetate] copolymer. The heat conducting unit may be formed of a composite material. The composite material may include, for example, reinforced plastics, ceramic matrix composites, and metal matrix composites. The heat conducting unit may comprise a heat pipe, metal or ceramic.

The heat conducting unit may be any design, shape, and/or size. Examples of possible shapes or designs include but are not limited to: mathematical shapes (e.g., circular, triangular, square, rectangular, pentagonal, or hexagonal), two-dimensional geometric shapes, multi-dimensional geometric shapes, curves, polygons, polyhedral, polytopes, minimal surfaces, ruled surfaces, non-orientable surfaces, quadrics, pseudospherical surfaces, algebraic surfaces, miscellaneous surfaces, riemann surfaces, box-drawing characters, cuisenaire rods, geometric shapes, shapes with metaphorical names, symbols, unicode geometric shapes, other geometric shapes, partial shapes or combination of shapes thereof.

The heat conducting unit may be insulated with insulating material to minimize heat loss. The insulating material may be in any size, shape and design. The heat conducting unit may be fully covered by the insulating material. The head conducting unit may be partially covered by the insulating material. The heat conducting unit may comprise high thermal conductivity materials. The high thermal conductivity materials may comprise heat pipe, copper, or aluminum.

If the head conducting unit is a conductive plate, the conductive plate may have a thermal conductivity of at least about 1 Watt/meter-Kelvin (W/m-K), 2 W/m-K, 3 W/m-K, 4 W/m-K, 5 W/m-K, 10 W/m-K, 20 W/m-K, 30 W/m-K, 40 W/m-K, 50 W/m-K, 100 W/m-K, 200 W/m-K or greater at a temperature of 25° C. In some cases, the conductive plate may have a thermal conductivity of at most about 500 W/m-K, 400 W/m-K, 300 W/m-K, 200 W/m-K, 100 W/m-K, 50 W/m-K, 40 W/m-K, 30 W/m-K, 20 W/m-K, 10 W/m-K, 5 W/m-K, or less at a temperature of 25° C. The conductive plate may be in any size, shape and design. In one example, the conductive plate is made of copper, and the dimension of the copper plate is 40 mm×40 mm×10 mm.

If the heat conducting unit is a heat pipe, the heat pipe may have a thermal conductivity of at least about 1 W/m-K, 2 W/m-K, 3 W/m-K, 4 W/m-K, 5 W/m-K, 10 W/m-K, 20 W/m-K, 30 W/m-K, 40 W/m-K, 50 W/m-K, 100 W/m-K, 200 W/m-K or greater at a temperature of 25° C. In some cases, the heat pipe may have a thermal conductivity of at most about 500 W/m-K, 400 W/m-K, 300 W/m-K, 200 W/m-K, 100 W/m-K, 50 W/m-K, 40 W/m-K, 30 W/m-K, 20 W/m-K, 10 W/m-K, 5 W/m-K, or less at a temperature of 25° C. The heat pipe may be designed to work at a temperature between −40° C. and 80° C., −30° C. and 70° C., −20° C. and 60° C., −10° C. and 50° C., 0° C. and 40° C., or 10° C. and 30° C. In some cases, the heat pipe may work at a temperature either lower than −40° C., or higher than 80° C. The heat pipe may be in any size, shape and design.

The heat pipe may have a length (L) of at least about 0.1 meters (“m”), 0.2 m, 0.3 m, 0.4 mm, 0.5 m, 0.6 m, 0.7 m, 0.8 m, or greater. In some cases, the heat pipe may have a length (L) of at most about 0.8 m, 0.7 m, 0.6 m, 0.5 m, 0.4 m, 0.3 m, 0.2 m, 0.1 m, or less. The heat pipe may have a diameter of at least about 0.001 meters (“m”), 0.002 m, 0.003 m, 0.004 mm, 0.005 m, 0.006 m, 0.007 m, 0.008 m, or greater. In some cases, the heat pipe may have a diameter of at most about 0.01 m, 0.009 m, 0.008 m, 0.007 m, 0.006 m, 0.005 m, 0.004 m, 0.003 m, 0.002 m, 0.001 m or less. In one example, the heat pipe has a length of 0.15 m and a diameter of 0.008 m, and the heat pipe is designed to work at a temperature between −30° C. and 70° C.

The thermoelectric system may comprise a second heat exchanger. The second heat exchanger may be coupled to and in thermal communication with the thermoelectric generator. The second heat exchanger may be coupled to and in thermal communication with the one or more heat conducting units. The second heat exchanger may be configured to collect the thermal energy from or dissipate the thermal energy to the thermal storage material.

The second heat exchanger may be in thermal communication with the one or more heat conducting units. If the second heat exchanger collects thermal energy, the second heat exchanger may provide the heat to adjacent components (e.g., one or more heat conducting units). If the second heat exchanger dissipates thermal energy, the second heat exchanger may expel the thermal energy from adjacent components (e.g., one or more heat conducting units). The second heat exchanger can be sufficiently thermally conductive to remove heat from the adjacent components and expel it to the thermal storage material.

The second heat exchanger may be in any design, shape, and/or size. The second heat exchanger may comprise one or more heat exchanger components. The heat exchanger components may be in any design, shape, and/or size. Examples of possible shapes or designs include but are not limited to: mathematical shapes (e.g., circular, triangular, square, rectangular, pentagonal, or hexagonal), two-dimensional geometric shapes, multi-dimensional geometric shapes, curves, polygons, polyhedral, polytopes, minimal surfaces, ruled surfaces, non-orientable surfaces, quadrics, pseudospherical surfaces, algebraic surfaces, miscellaneous surfaces, riemann surfaces, box-drawing characters, cuisenaire rods, geometric shapes, shapes with metaphorical names, symbols, unicode geometric shapes, other geometric shapes, partial shapes or combination of shapes thereof. The number of heat exchanger components of the second heat exchanger may be at least 1, 2, 3, 4, 5, 6, 7, 8, 9, 10, or more.

The heat exchanger components may be plates. The second heat exchanger may comprise a plurality of metal plates. The number of metal plates may be at least 1, 2, 3, 4, 5, 6, 7, 8, 9, 10, or more. If the heat conducting unit is a heat pipe, the individual metal plates of the plurality of metal plates may project away from the heat conducting unit along a direction that may be angled with respect to a longitudinal axis of the heat conducting unit. The angle with respect to a longitudinal axis of the heat conducting unit may be at least about 10°, 20°, 30°, 40°, 50°, 60°, 70°, 80°, 90°, or greater. In some cases, the angle with respect to a longitudinal axis of the heat conducting unit may be at most about 90°, 80°, 70°, 60°, 50°, 40°, 30°, 20°, 100 or less. The individual metal plates of the plurality of metal plates may project away from the heat conducting unit along a direction that may be orthogonal to a longitudinal axis of the heat conducting unit.

The heat exchange components may be one or more conductive plates. A given conductive plate of the one or more conductive plate may have a thermal conductivity of at least about 1 Watt/meter-Kelvin (W/m-K), 2 W/m-K, 3 W/m-K, 4 W/m-K, 5 W/m-K, 10 W/m-K, 20 W/m-K, 30 W/m-K, 40 W/m-K, 50 W/m-K, 100 W/m-K, 200 W/m-K or greater at a temperature of 25° C. In some cases, the given conductive plate may have a thermal conductivity of at most about 500 W/m-K, 400 W/m-K, 300 W/m-K, 200 W/m-K, 100 W/m-K, 50 W/m-K, 40 W/m-K, 30 W/m-K, 20 W/m-K, 10 W/m-K, 5 W/m-K, or less at a temperature of 25° C.

The second heat exchanger may be formed of a metallic (or metal-containing) material. The second heat exchanger may include one or more elemental metals. For example, the metallic material may include one or more of aluminum, titanium, copper, iron, steel, tin, tungsten, molybdenum, tantalum, cobalt, bismuth, cadmium, titanium, zirconium, antimony, manganese, beryllium, chromium, germanium, vanadium, gallium, hafnium, indium, niobium, rhenium and thallium, and their alloys. The second heat exchanger may be formed of a semiconductor-containing material, such as silicon or a silicide. The second heat exchanger may be formed of a polymeric material. The polymeric material may include one or more polymers. For example, the polymeric material may include one or more of polyvinyl chloride, polyvinylidene chloride, polyethylene, polyisobutene, and poly[ethylene-vinylacetate] copolymer. The second heat exchanger may be formed of a composite material. The composite material may include, for example, reinforced plastics, ceramic matrix composites, and metal matrix composites. In one example, the second heat exchanger comprises four conductive plates, which are made of copper, and at least one of the four conductive plates has a dimension of 10 mm×10 mm×1 mm.

The container may be formed of a metallic (or metal-containing) material. The container may include one or more elemental metals. For example, the metallic material may include one or more of aluminum, titanium, copper, iron, steel, tin, tungsten, molybdenum, tantalum, cobalt, bismuth, cadmium, titanium, zirconium, antimony, manganese, beryllium, chromium, germanium, vanadium, gallium, hafnium, indium, niobium, rhenium and thallium, and their alloys. The container may be formed of a semiconductor-containing material, such as silicon or a silicide. The container may be formed of a polymeric material. The polymeric material may include one or more polymers. For example, the polymeric material may include one or more of polyvinyl chloride, polyvinylidene chloride, polyethylene, polyisobutene, and poly[ethylene-vinylacetate] copolymer. The container may be formed of a composite material. The composite material may include, for example, reinforced plastics, ceramic matrix composites, and metal matrix composites.

The container may comprise insulating materials. The insulating materials may comprise, but not limited to, microporous silica, vacuum insulated panel, silica aerogel, polyurethane rigid panel, foil faced polyurethane rigid panel, polyisocyanurate spray foam, closed-cell polyurethane spray foam, phenolic spray form, thinsulate clothing insulation, urea-formaldehyde panels, urea foam, extruded expanded polystyrene, polystyrene board, phenolic rigid panel, urea-formaldehyde foam, high density fiberglass batts, extruded expended polystyrene, icynene loose-fill, molded expanded polystyrene, home foam, rice hulls, fiberglass batts, cotton batts, icynene spray, cardboard, rock and slag wool batts, cellulose loose-fill, cellulose wet-spray, rock and slag wool loose-fill, fiberglass loose-fill, polyethylene foam, cementitious foam, perlite loose-fill, wood panels, fiberglass rigid panel, vermiculite loose-fill, straw bale, papercrete, softwood, woodchips and other loose-fill wood products, aerated concrete, cellular concrete, snow, hardwood, brick, glass, poured concrete, fiberglass, mineral wool, cellulose, polyurethane foam and polystyreneor, or any other thermally insulating materials.

The container may comprise a first insulation component and a second insulation component. The first insulation component may seal the second insulation component. The sealing may be hermetically sealing. The sealing may not be hermetically sealing. The first insulation component may be made of styrofoam. The first insulation component may have a thermal conductivity of at most about 1 W/m-K, 0.9 W/m-K, 0.8 W/m-K, 0.7 W/m-K, 0.6 W/m-K, 0.5 W/m-K, 0.1 W/m-K, 0.05 W/m-K, 0.01 W/m-K, or less at a temperature of 25° C. In some cases, the first insulation component may have a thermal conductivity of at least about 0.01 W/m-K, 0.05 W/m-K, 0.1 W/m-K, 0.5 W/m-K, 0.6 W/m-K, 0.7 W/m-K, 0.8 W/m-K, 0.9 W/m-K, 1 W/m-K, or greater at a temperature of 25° C. The first insulation component may be a cover and the second insulation component may be a tank. The second insulation component may be a vacuum flask.

The thermal storage material can be a high heat capacity material. The high heat capacity material may comprise water. The high heat capacity material may be phase change material. The phase change material may comprise polyethylene glycol, hexadecane, pentadecane, heptadecane, and octadecane. The rate of heat exchange between the thermal storage material and the ambient environment through the container may be at most 10 W, 9 W, 8 W, 7 W, 6 W, 5 W, 4 W, 3 W, 2 W, 1 W, or less. In some cases, the rate of heat exchange between the thermal storage material and the ambient environment through the container may be at least 1 W, 2 W, 3 W, 4 W, 5 W, 6 W, 7 W, 8 W, 9 W, 10 W, or more.

The thermoelectric system may comprise a thermally conductive material, such as a thermally conductive adhesive. The thermally conductive adhesive may be disposed between the thermoelectric generator and the first heat exchanger. The thermally conductive adhesive may have a thermal conductivity of at least about 0.1 W/m-K, 0.2 W/m-K, 0.3 W/m-K, 0.4 W/m-K, 0.5 W/m-K, 0.6 W/m-K, 0.7 W/m-K, 0.8 W/m-K, 0.9 W/m-K, 1 W/m-K, 1.5 W/m-K, 2.5 W/m-K or greater at a temperature of 25° C. In some cases, the thermally conductive adhesive may have a thermal conductivity of at most about 2.5 W/m-K, 1.5 W/m-K, 1 W/m-K, 0.9 W/m-K, 0.8 W/m-K, 0.7 W/m-K, 0.6 W/m-K, 0.5 W/m-K, 0.3 W/m-K, 0.2 W/m-K, 0.1 W/m-K, or less at a temperature of 25° C. The work-life time of the thermally conductive adhesive may be at least 1 hour, 5 hours, 10 hours, 15 hours, 20 hours, 1 day, 2 days, or longer. In some cases, the work-life time of the thermally conductive adhesive may be at most about 2 days, 1 day, 20 hours, 15 hours, 10 hours, 5 hours, 1 hour, or less.

The thermoelectric system may further comprise an additional thermally conductive material, such as an additional thermally conductive adhesive. The additional thermally conductive adhesive may be disposed between the thermoelectric generator and the one or more heat conducting units. The additional thermally conductive adhesive may have a thermal conductivity of at least about 0.1 W/m-K, 0.2 W/m-K, 0.3 W/m-K, 0.4 W/m-K, 0.5 W/m-K, 0.6 W/m-K, 0.7 W/m-K, 0.8 W/m-K, 0.9 W/m-K, 1 W/m-K, 1.5 W/m-K, 2.5 W/m-K or greater at a temperature of 25° C. In some cases, the additional thermally conductive adhesive may have a thermal conductivity of at most about 2.5 W/m-K, 1.5 W/m-K, 1 W/m-K, 0.9 W/m-K, 0.8 W/m-K, 0.7 W/m-K, 0.6 W/m-K, 0.5 W/m-K, 0.3 W/m-K, 0.2 W/m-K, 0.1 W/m-K, or less at a temperature of 25° C. The work-life time of the additional thermally conductive adhesive may be at least about 1 hour, 5 hours, 10 hours, 15 hours, 20 hours, 1 day, 2 days, or longer. In some cases, the work-life time of the additional thermally conductive adhesive may be at most about 2 days, 1 day, 20 hours, 15 hours, 10 hours, 5 hours, 1 hour, or less.

The additional thermally conductive adhesive may have the same thermal conductivity as the thermally conductive adhesive. The additional thermally conductive adhesive may have a different thermal conductivity as the thermally conductive adhesive. The additional thermally conductive adhesive may have the same work-life time as the thermally conductive adhesive. The additional thermally conductive adhesive may have a different work-life time as the thermally conductive adhesive.

The thermoelectric generator may generate power upon flow of the thermal energy (i) from the first heat exchanger to the thermoelectric generator, or (ii) from the second heat exchanger to the thermoelectric generator. The thermoelectric generator may be configured to generate power upon flow of thermal energy from the second heat exchanger to the thermoelectric generator during night time. The night time may be the time after sunset and before sunrise. The thermoelectric generator may be configured to generate power upon flow of thermal energy from the first heat exchanger to the thermoelectric generator during day time. The day time may be the time after sunrise and before sunset.

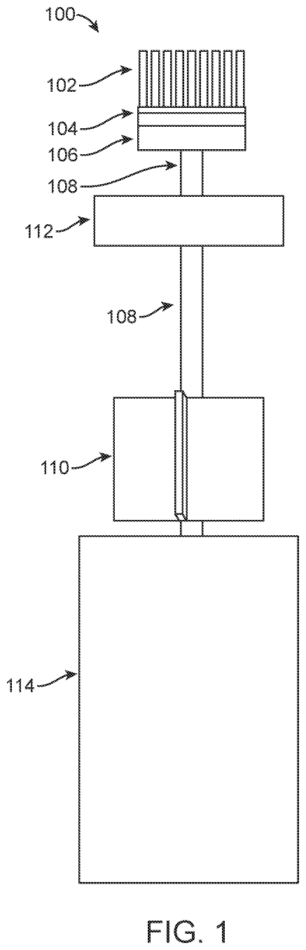

FIG. 1 shows an example of a thermoelectric system 100. The thermoelectric system may comprise a first heat exchanger 102 configured to collect thermal energy from or dissipate thermal energy to an ambient environment; a thermoelectric generator 104 comprising a plurality of thermoelectric elements; heat conducting units 106 and 108 that are coupled to the thermoelectric generator 104; a second heat exchanger 110 coupled to and in thermal communication with the heat conducting units 106 and 108; and a container 112 and 114 configured to hold the second heat exchanger 110 and a thermal storage material and insulate the thermal storage material from an environment external to the container. The first heat exchanger 102 may be a heat sink. The thermoelectric generator 104 may be coupled to and in thermal communication with the first heat exchanger 102. The heat conducting unit 106 may be a conductive plate. The heat conducting unit 108 may be a heat pipe. The container may comprise a first insulation component 112 and a second insulation component 114. The first insulation component 112 may be a cover and the second insulation component 114 may be a container (e.g., a tank). The first insulation component 112 may seal the second insulation component 114. The second heat exchanger 110 may facilitate the exchange of thermal energy between the ambient environment and the thermal storage material in the container 112 and 114. The thermal storage material may have a high capacity such that it can maintain a particular temperature even while the temperature of the ambient environment changes. The thermoelectric generator 104 can use the difference in temperature between the thermal storage material and the ambient environment to generate power. In this way, natural temperature fluctuations can be used to generate power. The thermoelectric generator 104 can use temperature changes as small as 2° C. or less to generate hundreds of microwatts of power.

The thermoelectric system 100 may additionally have power management integrated circuits (PMICs) that can regulate the power generated by the thermoelectric generator 104. The PMICs may, for example, boost the voltage of the output power. The thermoelectric system 100 may additionally have an energy storage unit (e.g., a battery) to store power that is not immediately used or needed.

The thermoelectric system 100 may further comprise one or more sensors that obtain power from the thermoelectric system 100. The sensors may be integrated into the thermoelectric system 100, or they may be separate components. The sensors may be connected to the thermoelectric generator 104, a PMIC, or a battery via wires or inductive coupling. The sensors may comprise, but are not limited to, geophone, hydrophone, lace sensor, microphone, seismometer, sound locator, air flow meter, air-fuel ratio (AFR) sensors, blind spot monitor, defect detector, hall effect sensor, wheel speed sensor, airbag sensors, coolant temperature sensor, fuel level sensor, fuel pressure sensor, light sensor, manifold absolute pressure (MAP) sensor, oxygen sensor, oil level sensor, breathalyzer, carbon dioxide sensor, carbon monoxide sensor, electrochemical gas sensor, hydrogen sensor, current sensor, daly detector, electroscope, magnetic anomaly detector, microelectromechanical system (MEMS) magnetic field sensor, metal detector, radio direction finder, voltage detector, actinometer, air pollution sensor, ceilometer, gas detector, humistor, leaf sensor, rain gauge, rain sensor, snow gauge, soil moisture sensor, stream gauge, tide gauge, mass flow sensor, water meter, cloud chamber, neuron detection, air speed indicator, depth gauge, magnetic compass, turn coordinator, flame detector, photodiode, wavefront sensor, barometer, pressure sensor, level sensor, viscometer, bolometer, colorimeter, thermometer, proximity sensor, reed switch, and biosensor.

The sensors may measure one or more environment parameters. The one or more environment parameters may be related to any characteristics of the environment. The one or more environment parameters may comprise, but not limited to, temperature, humidity, luminance, wind direction, wind speed, pH level, carbon dioxide concentration, moisture, chemical composition, currents and water turbulence, salinity, nutrient element, turbidity, dissolved oxygen, algae and phytoplankton, water level, noise level, atmospheric (barometric) pressure, precipitation, and solar radiation.

The thermoelectric system 100 may have a transmitter configured to transmit data from the sensors to a remotely-located computing device. In this way, the thermoelectric system may serve as a standalone internet-of-things (IoT) device that need not be plugged in or connected to a wired network.

### Methods for Generating Power

In an aspect, a method for generating power may comprise providing a thermoelectric system. The thermoelectric system may comprise a first heat exchanger configured to collect thermal energy from or dissipate the thermal energy to an ambient environment, and a thermoelectric generator comprising a plurality of thermoelectric elements. The thermoelectric generator may be coupled to and in thermal communication with the first heat exchanger. The thermoelectric system may further comprise one or more heat conducting units coupled to the thermoelectric generator, a second heat exchanger coupled to and in thermal communication with the one or more heat conducting units, and a container configured to (i) contain the second heat exchanger and a thermal storage material and (ii) insulate the thermal storage material from an external to the container such that a rate of heat exchange between the thermal storage material and the ambient environment through the container is at most about 10 watts (W). When the second heat exchanger is in the container, the second heat exchanger may collect the thermal energy from or dissipates the thermal energy to the thermal storage material. The method for generating power may further comprise using the thermoelectric generator to generate power upon flow of the thermal energy from the first heat exchanger to the thermoelectric generator, or from the second heat exchanger to the thermoelectric generator. The method for generating power may further comprise directing the power to an energy storage system or an electrical load.

The first heat exchanger may be a heat sink. The heat sink may have a surface area between 400 mm² and 100000 mm². The first heat changer and the heat sink may be described as elsewhere herein. The thermoelectric generator, the plurality of thermoelectric elements, the second heat exchanger, and/or the thermal storage material may be as described elsewhere herein.

The thermoelectric system may further comprise a thermally conductive adhesive disposed between the thermoelectric generator and the first heat exchanger, wherein the thermally conductive adhesive has a thermal conductivity of at least 0.5 W/m-K at a temperature of 25° C. The thermally conductive adhesive may be as described elsewhere herein. The thermoelectric system may further comprise an additional thermally conductive adhesive disposed between the thermoelectric generator and the one or more heat conducting units, wherein the additional thermally conductive adhesive has a thermal conductivity of at least 0.5 W/m-K at a temperature of 25° C. The additional thermally conductive adhesive may be as described elsewhere herein.

The thermoelectric system may comprise one or more heat conducting units. The one or more heat conducting units may comprise one or more conductive plates, or one or more heat pipes. A heat conducting unit of the one or more heat conducting units may be coupled to the thermoelectric generator. The heat conducting unit may be as described elsewhere herein.

The container may comprise a first insulation component and a second insulation component, wherein the first insulation component seals the second insulation component. The first insulation component may be a cover and the second insulation component may be a tank. The container, the first insulation component, and the second insulation component may be as described elsewhere herein.

At least a portion of the power may be stored in the energy storage system or used in the electrical load. The energy storage system or the electrical load may be in electrical communication with the thermoelectric generator. The energy storage system may be configured to store power generated by the thermoelectric generator. The power stored in the energy storage system may be at least about 10%, 20%, 30%, 40%, 50%, 60%, 70%, 80%, 90% or greater of the power generated by the thermoelectric generator. In some cases, the power stored in the energy storage system may be at most about 90%, 80%, 70%, 60%, 50%, 40%, 30%, 20%, 10%, or less of the power generated by the thermoelectric generator. The energy storage system may comprise a battery. The electrical load may be configured to consume power generated by the thermoelectric generator. The power consumed by the electrical load may be at least about 10%, 20%, 30%, 40%, 50%, 60%, 70%, 80%, 90% or greater of the power generated by the thermoelectric generator. In some cases, the power consumed by the electrical load may be at most about 90%, 80%, 70%, 60%, 50%, 40%, 30%, 20%, 10%, or less of the power generated by the thermoelectric generator.

### Methods for Forming Thermoelectric System

The components of the thermoelectric system (e.g., the first heat exchanger) may be formed by using one or more manufacturing techniques. The one or more manufacturing techniques may include subtractive manufacturing, injection molding, blow molding, or additive manufacturing processes. Subtractive manufacturing or additive manufacturing may be three-dimensional (3D) printing.

Subtractive manufacturing may be used to create a target component of the thermoelectric system by successively cutting material away from a solid material (e.g., solid block of material). Injection molding may comprise a high-pressure injection of raw materials into one or more molds. The one or more molds may shape the raw material into the shape of the target component of the thermoelectric system. Additive manufacturing processes may be used to create the target component of the thermoelectric system by laying down successive layers of material, each of which can be seen as a thinly sliced horizontal cross-section of the target component of the thermoelectric system. Blow molding may comprise multiple steps. The multiple steps may comprise melting down the raw material, forming the raw material into a parison, placing the parison into a mold, and air blowing through the parison to push the material out to match the mold.

For example, the thermoelectric system 100 may be formed by forming the cover 112 and the container 114 using 3D printing or injection molding. As an alternative, the container 114 may be formed by blow molding.

One or more heat conducting units may be soldered together to ensure intimate thermal contact between each other. A given heat conducting unit and a second heat exchanger may be soldered together to ensure intimate thermal contact. The first heat exchanger, the thermoelectric generator, and the conductive plate may be held together by thermally conductive adhesive to minimize thermal contact resistance. The first insulation component and the second insulation component may have good thermal insulation properties to prevent heat leaking to the ambient environment.

A thermoelectric generator (e.g., the thermoelectric generator 104) may comprise a plurality of thermoelectric elements. A thermoelectric element can be formed using electrochemical etching. The thermoelectric element may be formed by cathodic or anodic etching, in some cases without the use of a catalyst. The thermoelectric element can be formed without use of a metallic catalysis. The thermoelectric element can be formed without providing a metallic coating on a surface of a substrate to be etched. This can also be performed using purely electrochemical anodic etching and suitable etch solutions and electrolytes. As an alternative, a thermoelectric can be formed using metal catalyzed electrochemical etching in suitable etch solutions and electrolytes, as described in, for example, PCT/US2012/047021, filed Jul. 17, 2012, PCT/US2013/021900, filed Jan. 17, 2013, PCT/US2013/055462, filed Aug. 16, 2013, PCT/US2013/067346, filed Oct. 29, 2013, each of which is entirely incorporated herein by reference.

A thermoelectric element can be formed using one or more sintering processes. The one or more sintering processes may comprise spark plasma sintering, electro sinter forging, pressureless sintering, microwave sintering, and liquid phase sintering. For example, the thermoelectric element can be formed using one of the techniques described in PCT/US2015/022312, filed Mar. 24, 2014, which is entirely incorporated herein by reference. The spark plasma sintering may be conducted by using a spark plasma sintering instrument. The spark plasma sintering instrument may apply external pressure and an electric field simultaneously to enhance the densification of a precursor of the thermoelectric element. The spark plasma sintering instrument may use a direct current (DC) pulse as the electric current to create spark plasma and spark impact pressure.

A thermoelectric element can alternatively be formed by heating an uncompacted powder in a mold as described in U.S. Patent Publication 2016/0380175, filed on Dec. 29, 2016, which is entirely incorporated herein by reference.

### Computer Control Systems

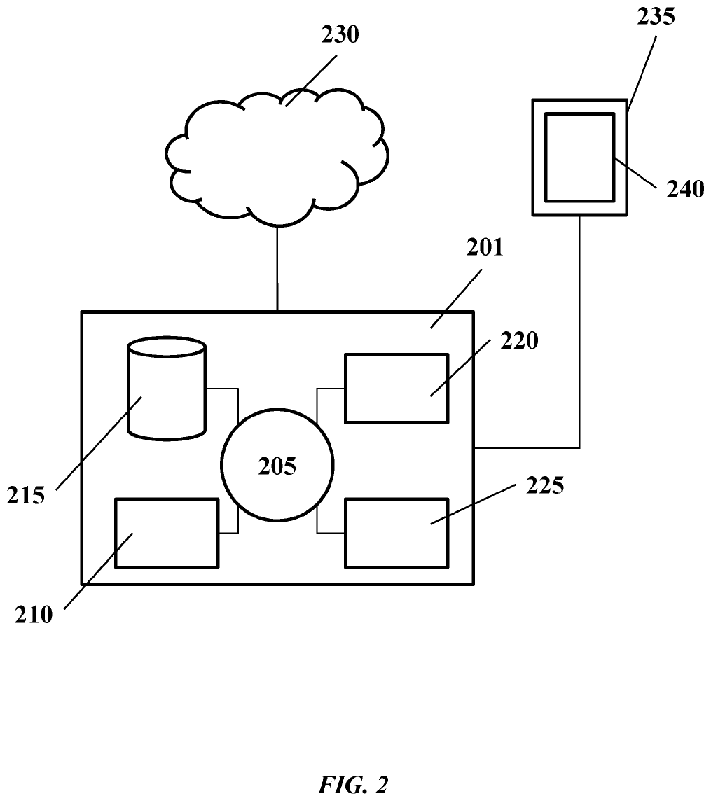

The present disclosure provides computer systems that are programmed to implement methods of the disclosure. FIG. 2 shows a computer system 201 that is programmed or otherwise configured to control the thermoelectric system disclosed herein. The computer system 201 can regulate various aspects of the present disclosure, such as, for example, detecting and controlling power produced by the thermoelectric generator, and detecting and controlling the power stored in the energy storage system. The computer system 201 can be an electronic device of a user or a computer system that is remotely located with respect to the electronic device. The electronic device can be a mobile electronic device.

The computer system 201 includes a central processing unit (CPU, also “processor” and “computer processor” herein) 205, which can be a single core or multi core processor, or a plurality of processors for parallel processing. The computer system 201 also includes memory or memory location 210 (e.g., random-access memory, read-only memory, flash memory), electronic storage unit 215 (e.g., hard disk), communication interface 220 (e.g., network adapter) for communicating with one or more other systems, and peripheral devices 225, such as cache, other memory, data storage and/or electronic display adapters. The memory 210, storage unit 215, interface 220 and peripheral devices 225 are in communication with the CPU 205 through a communication bus (solid lines), such as a motherboard. The storage unit 215 can be a data storage unit (or data repository) for storing data. The computer system 201 can be operatively coupled to a computer network (“network”) 230 with the aid of the communication interface 220. The network 230 can be the Internet, an internet and/or extranet, or an intranet and/or extranet that is in communication with the Internet. The network 230 in some cases is a telecommunication and/or data network. The network 230 can include one or more computer servers, which can enable distributed computing, such as cloud computing. The network 230, in some cases with the aid of the computer system 201, can implement a peer-to-peer network, which may enable devices coupled to the computer system 201 to behave as a client or a server.

The CPU 205 can execute a sequence of machine-readable instructions, which can be embodied in a program or software. The instructions may be stored in a memory location, such as the memory 210. The instructions can be directed to the CPU 205, which can subsequently program or otherwise configure the CPU 205 to implement methods of the present disclosure. Examples of operations performed by the CPU 205 can include fetch, decode, execute, and writeback.

The CPU 205 can be part of a circuit, such as an integrated circuit. One or more other components of the system 201 can be included in the circuit. In some cases, the circuit is an application specific integrated circuit (ASIC).

The storage unit 215 can store files, such as drivers, libraries and saved programs. The storage unit 215 can store user data, e.g., user preferences and user programs. The computer system 201 in some cases can include one or more additional data storage units that are external to the computer system 201, such as located on a remote server that is in communication with the computer system 201 through an intranet or the Internet.

The computer system 201 can communicate with one or more remote computer systems through the network 230. For instance, the computer system 201 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 201 via the network 230.

Methods as described herein can be implemented by way of machine (e.g., computer processor) executable code stored on an electronic storage location of the computer system 201, such as, for example, on the memory 210 or electronic storage unit 215. The machine executable or machine-readable code can be provided in the form of software. During use, the code can be executed by the processor 205. In some cases, the code can be retrieved from the storage unit 215 and stored on the memory 210 for ready access by the processor 205. In some situations, the electronic storage unit 215 can be precluded, and machine-executable instructions are stored on memory 210.

The code can be pre-compiled and configured for use with a machine having a processer adapted to execute the code or can be compiled during runtime. The code can be supplied in a programming language that can be selected to enable the code to execute in a pre-compiled or as-compiled fashion.

Aspects of the systems and methods provided herein, such as the computer system 201, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 201 can include or be in communication with an electronic display 235 that comprises a user interface (UI) 240 for providing, for example, percentage of energy stored in the energy storage system. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 205.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1. A thermoelectric system, comprising:
a first heat exchanger configured to collect thermal energy from or dissipate said thermal energy to an ambient environment;
a thermoelectric generator comprising a plurality of thermoelectric elements, wherein said thermoelectric generator is coupled to and in thermal communication with said first heat exchanger;
one or more heat conducting units coupled to said thermoelectric generator;
a second heat exchanger coupled to and in thermal communication with said one or more heat conducting units; and
a container configured to (i) hold said second heat exchanger and a thermal storage material, and (ii) insulate said thermal storage material from an environment external to said container, wherein said second heat exchanger collects said thermal energy from or dissipates said thermal energy to said thermal storage material.

2. The system of claim 1, wherein said first heat exchanger is a heat sink.

3. The system of claim 2, wherein said heat sink has a surface area between 400 mm² and 100000 mm².

4. The system of claim 1, further comprising a thermally conductive adhesive disposed between said thermoelectric generator and said first heat exchanger, wherein said thermally conductive adhesive has a thermal conductivity of at least 0.5 Watts/meter-Kelvin (W/m-K) at a temperature of 25° C.

5. The system of claim 4, further comprising an additional thermally conductive adhesive disposed between said thermoelectric generator and said one or more heat conducting units, wherein said additional thermally conductive adhesive has a thermal conductivity of at least 0.5 W/m-K at a temperature of 25° C.

6. The system of claim 1, wherein said one or more heat conducting units comprise a thermally conductive material.

7. The system of claim 6, wherein said thermally conductivity material has a thermal conductivity of at least 1 W/m-K at a temperature of 25° C.

8. The system of claim 1, wherein said container comprises a first insulation component and a second insulation component, wherein said first insulation component seals said second insulation component.

9. The system of claim 8, wherein said first insulation component is a cover and said second insulation component is a tank.

10. The system of claim 1, wherein said thermoelectric generator generates power upon flow of said thermal energy (i) from said first heat exchanger to said thermoelectric generator, or (ii) from said second heat exchanger to said thermoelectric generator.

11. The system of claim 1, wherein a rate of heat exchange between said thermal storage material and said ambient environment is at most 10 Watts (W).

12. The system of claim 1, further comprising a sensor configured to obtain data about said ambient environment.

13. The system of claim 12, wherein said sensor is selected from the group consisting of a temperature sensor, a humidity sensor, a luminance sensor, a wind direction sensor, a wind speed sensor, a pH level sensor, a carbon dioxide concentration sensor, a moisture sensor, and a chemical composition sensor.

14. The system of claim 13, further comprising a transmitter configured to transmit data obtained by said sensor to a remote computing device.

15. A method for generating power, comprising:
providing a thermoelectric system comprising (i) a first heat exchanger configured to collect thermal energy from or dissipate said thermal energy to an ambient environment; (ii) a thermoelectric generator comprising a plurality of thermoelectric elements, wherein said thermoelectric generator is coupled to and in thermal communication with said first heat exchanger; (iii) one or more heat conducting units coupled to said thermoelectric generator; (iv) a second heat exchanger coupled to and in thermal communication with said one or more heat conducting units; and (v) a container that (i) holds said second heat exchanger and a thermal storage material and (ii) insulates said thermal storage material from an external to said container, wherein said second heat exchanger collects said thermal energy from or dissipates said thermal energy to said thermal storage material;
using said thermoelectric generator to generate power upon flow of said thermal energy (i) from said first heat exchanger to said thermoelectric generator, or (ii) from said second heat exchanger to said thermoelectric generator; and
directing said power to an energy storage system or an electrical load.

16. The method of claim 15, wherein said first heat exchanger is a heat sink.

17. The method of claim 16, wherein said heat sink has a surface area between 400 mm² and 100000 mm².

18. The method of claim 15, wherein said thermoelectric system further comprises a thermally conductive adhesive disposed between said thermoelectric generator and said first heat exchanger, wherein said thermally conductive adhesive has a thermal conductivity of at least 0.5 W/m-K at a temperature of 25° C.

19. The method of claim 18, wherein said thermoelectric system further comprises an additional thermally conductive adhesive disposed between said thermoelectric generator and said one or more heat conducting units, wherein said additional thermally conductive adhesive has a thermal conductivity of at least 0.5 W/m-K at a temperature of 25° C.

20. The method of claim 15, wherein said one or more heat conducting units comprise a thermally conductive material.

21. The method of claim 20, wherein said thermally conductive material has a thermal conductivity of at least 1 W/m-K at a temperature of 25° C.

22. The method of claim 15, wherein said container comprises a first insulation component and a second insulation component, wherein said first insulation component seals said second insulation component.

23. The method of claim 22, wherein said first insulation component is a cover and said second insulation component is a tank.

24. The method of claim 15, wherein at least a portion of said power is stored in said energy storage system or used in said electrical load.

25. A method of forming a thermoelectric system comprising: (i) a first heat exchanger configured to collect thermal energy from or dissipate said thermal energy to an ambient environment; (ii) a thermoelectric generator comprising a plurality of thermoelectric elements, wherein said thermoelectric generator is coupled to and in thermal communication with said first heat exchanger; (iii) one or more heat conducting units coupled to said thermoelectric generator; (iv) a second heat exchanger coupled to and in thermal communication with said one or more heat conducting units; and (v) container configured to (i) contain said second heat exchanger and a thermal storage material, and (ii) insulate said thermal storage material from an environment external to said container, wherein when said second heat exchanger is in said container, and wherein said second heat exchanger collects said thermal energy from or dissipates said thermal energy to said thermal storage material.
